(19) United States
(12) Patent Application Publication
(10) Pub. No.: US 2026/0188406 A1
(43) Pub. Date: Jul. 2, 2026

(54) DEFECT DETECTION METHOD FOR MEMORY DEVICE

(71) Applicant: Powerchip Semiconductor Manufacturing Corporation, Hsinchu (TW)

(72) Inventors: Chia-Yen Wu, Hsinchu County (TW); Chun-Hung Lee, Hsinchu (TW); Tsai-Ko Teng, Hsinchu City (TW)

(73) Assignee: Powerchip Semiconductor Manufacturing Corporation, Hsinchu (TW)

(21) Appl. No.: 19/055,516

(22) Filed: Feb. 18, 2025

(30) Foreign Application Priority Data
Jan. 2, 2025 (TW) 114100174

(51) Int. Cl. G11C 29/12

(52) U.S. Cl. CPC G11C 29/12005; G11C 2029/1204

(57) ABSTRACT

A defect detection method for a memory device is provided. The memory device includes a memory array. The memory array performs an access operation according to a reference voltage. The defect detection method includes: dividing the memory array into multiple memory blocks; adjusting a voltage value of the reference voltage to sequentially perform the access operation on the memory blocks, and receiving multiple defect counts of the memory blocks after the access operation; and judging a defect type of the memory blocks according to the defect counts.

### CROSS-REFERENCE TO RELATED APPLICATION

This application claims the priority benefit of Taiwan application serial no. 114100174, filed on Jan. 2, 2025. The entirety of the above-mentioned patent application is hereby incorporated by reference herein and made a part of this specification.

### BACKGROUND

### Technical Field

The disclosure relates to a method for an electronic device, and in particular to a defect detection method for a memory device.

### Description of Related Art

Conventional testing methods for memory devices may obtain defect quantities in memory arrays of the memory devices. However, when the defect quantities in the memory arrays are large, the types of defects in the memory arrays are difficult to be determined.

### SUMMARY

The disclosure provides a defect detection method for a memory device, which can determine the type of defects in a memory array.

A defect detection method of the disclosure is used for a memory device. The memory device includes a memory array. The memory array performs an access operation according to a reference voltage. The defect detection method includes: dividing the memory array into multiple memory blocks; adjusting a voltage value of the reference voltage to sequentially perform the access operation on the memory blocks, and receiving multiple defect counts of the memory blocks after the access operation; and judging a defect type of the memory blocks according to the defect counts.

Based on the above, in the disclosure, the memory array is divided into the memory blocks to obtain the defect counts of the memory blocks after the access operation. It should be noted that the defect count of a single memory block is lower than the defect count of the memory array. In this way, the defect type of the memory block may be easily judged.

### BRIEF DESCRIPTION OF THE DRAWINGS

FIG. 1 is a schematic diagram of an operation of a memory device according to an embodiment of the disclosure.

FIG. 2 is a flowchart of a defect detection method according to an embodiment of the disclosure.

FIG. 3 is a flowchart of a defect detection method according to an embodiment of the disclosure.

FIG. 4 is a defect statistical diagram according to an embodiment of the disclosure.

FIG. 5 is a statistical diagram of memory block quantities according to an embodiment of the disclosure.

FIG. 6 is a flowchart of a defect detection method according to an embodiment of the disclosure.

FIG. 7 is a flowchart of a defect detection method according to an embodiment of the disclosure.

FIG. 8 is a schematic diagram for judging a reference voltage range according to an embodiment of the disclosure.

FIG. 9 is a flowchart of a defect detection method according to an embodiment of the disclosure.

FIG. 10 is a defect statistical diagram according to an embodiment of the disclosure.

### DESCRIPTION OF THE EMBODIMENTS

Some embodiments of the disclosure will be described in detail with reference to the drawings. For the reference numerals cited in the following description, when the same reference numerals appear in different drawings, the reference numerals will be regarded as referring to the same or similar elements. The embodiments are only a part of the disclosure and do not disclose all possible implementations of the disclosure. More specifically, the embodiments are merely examples in the claims of the disclosure.

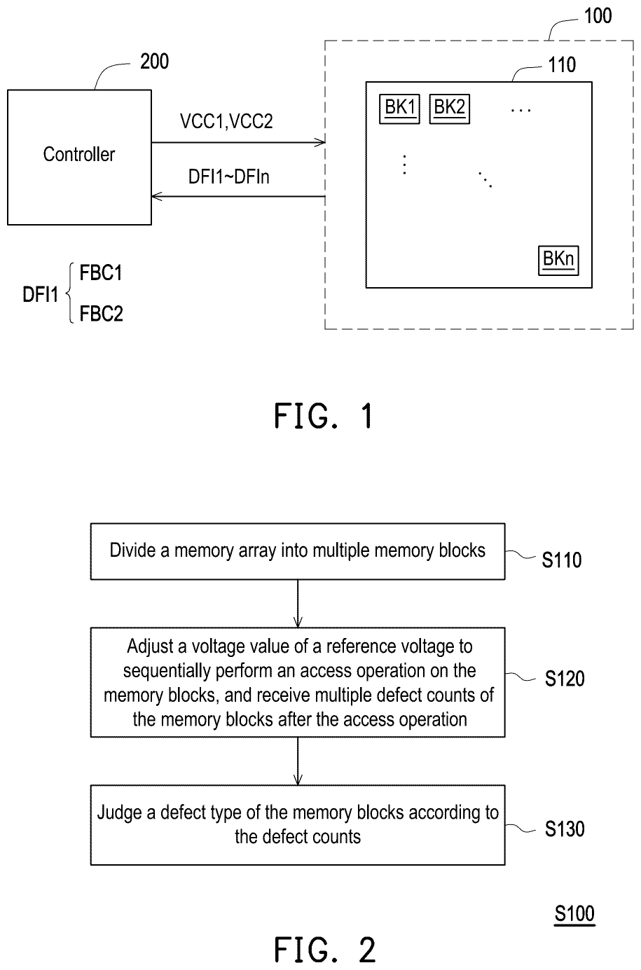

Please refer to FIG. 1 and FIG. 2. FIG. 1 is a schematic diagram of an operation of a memory device according to an embodiment of the disclosure. FIG. 2 is a flowchart of a defect detection method according to an embodiment of the disclosure. In the embodiment, a memory device 100 includes a memory array 110. For example, the memory device 100 may be a static random access memory (SRAM) device, but the disclosure is not limited thereto. In the embodiment, the memory array 110 includes multiple memory cells. The memory array 110 performs an access operation according to reference voltages VCC1 and VCC2. For example, the access operation includes a write operation and a read operation. The memory array 110 performs the write operation according to the reference voltage VCC1. The memory array 110 performs the read operation according to the reference voltage VCC2. A defect detection method S100 may be, for example, executed by a controller 200. For example, the controller 200 may be a memory controller in the memory device 100 or a testing circuit located outside the memory device 100.

In the embodiment, the defect detection method S100 includes steps S110 to S130. In step S110, the memory array 110 is divided into memory blocks BK1 to BKn. For example, taking the memory array 110 with 64 Mb as an example, the memory array 110 may be divided into 256 memory blocks BK1 to BKn (that is, n is equal to “256”).

In step S120, the controller 200 adjusts voltage values of the reference voltages VCC1 and VCC2 to sequentially perform the access operation on the memory blocks BK0 to BKn, and receives defect counts DFI1 to DFIn of the memory blocks BK1 to BKn after performing the access operation.

The defect count DFI1 of the memory block BK1 may change as the voltage values of reference voltages VCC1 and VCC2 change. The defect count DFI2 of the memory block BK2 may change as the voltage values of the reference voltages VCC1 and VCC2 change, and so on.

In step S130, the controller 200 judges defect types of the memory blocks BK1 to BKn according to the defect counts DFI1 to DFIn. For example, the controller 200 may define the defect type of the memory block BK1 according to the content of the defect count DFI1. The controller 200 may define the defect type of the memory block BK2 according to the content of the defect count DFI2, and so on.

It is worth mentioning here that the memory array 110 is divided into the memory blocks BK1 to BKn to obtain the defect counts DFI1 to DFIn. The defect count DFI1 of the memory block BK1 is lower than the defect count of the entire memory array 110. In this way, the defect type of the memory block BK1 may be easily judged. By analogy, the defect type of each of the memory blocks BK1 to BKn may be easily judged.

In the embodiment, each of the defect counts DFI1 to DFIn includes a failed bit count (FBC) and a failed bit line count (FBL). Taking the defect count DFI1 as an example, the defect count DFI1 includes a failed bit count FBC1 and a failed bit line count FBL1. The controller 200 may define the defect type of the memory block BK1 according to the failed bit count FBC1 and the failed bit line count FBL1.

For example, when the failed bit count FBC1 corresponding to the memory block BK1 is equal to “0” and the failed bit line count FBL1 corresponding to the memory block BK1 is equal to “0”, the controller 200 judges that the memory block BK1 is a pass memory block. In other words, based on the corresponding reference voltages VCC1 and VCC2, the memory block BK1 is not defective.

For example, when the failed bit count FBC1 corresponding to the memory block BK1 is greater than “0” and the failed bit line count FBL1 corresponding to the memory block BK1 is equal to “1”, the controller 200 judges that the memory block BK1 has a bit line failure. In other words, error bits are all concentrated on the same bit line.

For example, when the failed bit count FBC1 corresponding to the memory block BK1 is equal to a and the failed bit line count FBL1 corresponding to the memory block BK1 is greater than “1”, the controller 200 judges that the memory block BK1 has a bit defects.

For another example, when the failed bit line count FBL1 corresponding to the memory block BK1 is greater than a preset value (for example, “40”), the controller 200 judges that the memory block BK1 has a data (DQ) failure.

Furthermore, in some embodiments, the controller 200 may be operated to define different defect types according to specific quantity ranges of the failed bit count FBC1 and the failed bit line count FBL1. For example, when the failed bit count FBC1 is equal to “1”, the controller 200 judges that the memory block BK1 has a first defect type. When the failed bit count FBC1 is less than or equal to “2” (that is, FBC1≤2), the controller 200 judges that the memory block BK1 has a second defect type. When the failed bit count FBC1 is less than or equal to “4” (that is, FBC1≤4), the controller 200 judges that the memory block BK1 has a third defect type. When the failed bit count FBC1 is less than or equal to “100” (that is, FBC1≤100), the controller 200 judges that the memory block BK1 has a fourth defect type. The fourth defect type may include the bit line failure and/or a word line failure of the memory block BK1. When the failed bit count FBC1 is less than or equal to “1000” (that is, FBC1≤1000), the controller 200 judges that the memory block BK1 has a fifth defect type. The fifth defect type may include the bit line failure and/or the word line failure of the memory block BK1.

In addition, when the failed bit count FBC1 is equal to “2” and the failed bit line count FBL1 is less than or equal to “2” (that is, FBC1=2 and FBL1≤2), the controller 200 judges that the memory block BK1 has a sixth defect type. When the failed bit count FBC1 is equal to “3” and the failed bit line count FBL1 is less than or equal to “3” (that is, FBC1=3 and FBL1≤3), the controller 200 judges that the memory block BK1 has a seventh defect type. When the failed bit count FBC1 is equal to “4” and the failed bit line count FBL1 is less than or equal to “4” (that is, FBC1=4 and FBL1≤4), the controller 200 judges that the memory block BK1 has an eighth defect type.

Therefore, the controller 200 records at least one defect type of a selected memory block. The controller 200 may also display or list the at least one defect type of the selected memory block. The controller 200 records the at least one defect type and a defect address of the selected memory block. The controller 200 may also display or list the at least one defect type and the defect address of the selected memory block.

By analogy, the controller 200 may also define the defect types of the memory blocks BK2 to BKn using the same manner as above.

In the embodiment, the defect detection method S100 may be executed in a testing phase of the memory array 110.

In the embodiment, the controller 200 may select a functional test item to test the memory blocks BK1 to BKn to record failed bit counts and failed bit line counts of the memory blocks BK1 to BKn. The controller 200 may display the defect types and the defect addresses of the memory blocks BK1 to BKn using other functional test items.

In the embodiment, the controller 200 generates different status flags according to different defect types of the memory blocks BK1 to BKn, and decides whether to display the defect addresses corresponding to the defect types according to the status flags. For example, the status flags may be decided according to the failed bit counts of the memory blocks BK1 to BKn. For example, when the failed bit count of the memory block BK1 is greater than 0 and less than or equal to 100 (that is, 1<FBC≤100), the controller 200 may display the defect type and the defect address of the memory block BK1. For example, when the failed bit count of the memory block BK1 is greater than 100 (that is, FBC≥100), the controller 200 displays the defect type of the memory block BK1 but does not display the defect address of the memory block BK1. The defect address includes a memory array address, a memory block address, a word line address, a memory column address, and a data pin address.

In the embodiment, the failed bit counts and the sequence of the memory blocks BK1 to BKn may be used to decide whether to display the defect address corresponding to the defect type and display an address sequence.

Taking the memory block BK1 as an example, when the failed bit count is equal to 0, the controller 200 may judge that the memory block BK1 is a pass memory block, and generate a flag that the memory block BK1 is in a pass memory block status. In some embodiments, when the failed bit count is equal to 0, the controller 200 may generate the flag that the memory block BK1 is in the pass memory block status and record a pass address (that is, the address of the memory block BK1).

In some embodiments, when a failed bit count sum of the defect counts of the memory array is greater than a critical value (for example, 100 or 1000), the controller 200 stops recording the defect addresses. Therefore, when the failed bit count sum of the defect counts of the memory array is greater than the critical value (for example, 100 or 1000), the controller 200 stops recording the defect addresses of the subsequent memory blocks.

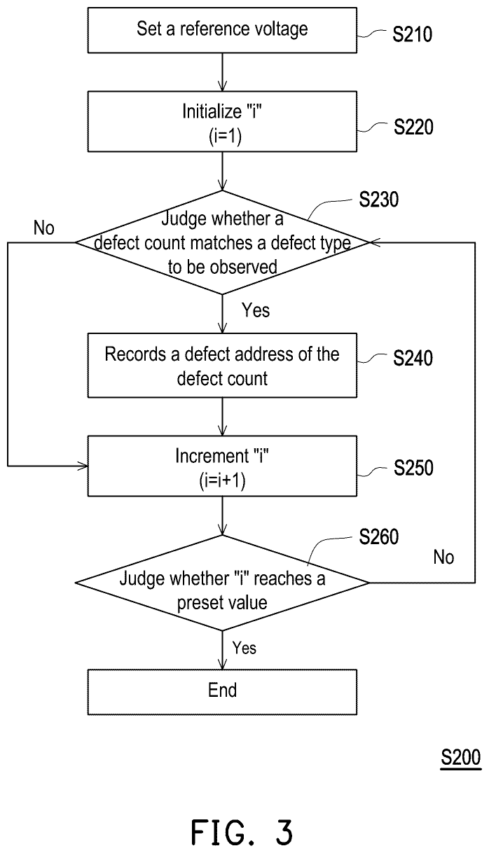

Please refer to FIG. 1 and FIG. 3. FIG. 3 is a flowchart of a defect detection method according to an embodiment of the disclosure. In the embodiment, a defect detection method S200 is used to record the defect counts DFI1 to DFIn. The defect detection method S200 includes steps S210 to S260. In step S210, the controller 200 sets the reference voltages VCC1 and VCC2. In step S220, the controller 200 initializes “i”. “i” may represent a memory block BK(i). In other words, “i” may represent the serial number of one of the memory blocks BK1 to BKn. In the embodiment, the controller 200 sets “i” to be “1” in step S220. Therefore, in step S220, “i” indicates the memory block BK1.

In step S230, the controller 200 receives the defect count DFI1 (that is, the defect count generated by the memory block BK1 after executing the access operation), and judges whether the defect count DFI1 matches a defect type to be observed according to the defect count DFI1. When the defect count DFI1 matches the defect type to be observed, the controller 200 records a defect address of the defect count DFI1 in step S240. For example, the defect address includes a word line address, a memory column address, and a data (DQ) pin address. Next, the controller 200 increments “i” (for example, i=i+1) in step S250. For example, the controller 200 may record the defect count DFI1 and the defect address of the defect count DFI1 in a memory circuit.

In step S260, the controller 200 judges whether “i” reaches a preset value. When “i” has not reached the preset value, the controller 200 returns to the operation of step S230. Therefore, the controller 200 judges whether the defect count DFI2 matches the defect type to be observed. When “i” reaches the preset value, the controller 200 ends the defect detection method S200.

In step S230, when the defect count DFI1 does not match the defect type to be observed, the controller 200 increments “i” (for example, i=i+1) in step S250, and performs the operation of step S260.

In the embodiment, the controller 200 may adjust at least one of the reference voltages VCC1 and VCC2 in step S210. For example, the controller 200 may increment or decrement at least one of the reference voltages VCC1 and VCC2 in step S210.

In the embodiment, during the process of executing the defect detection method S200 or before executing the defect detection method S200, the controller 200 counts the total number of the defect counts DFI1 to DFIn of the memory array 110. The controller 200 may decide whether to record the defect address according to the total number of the defect counts DFI1 to DFIn. For example, when the failed bit count sum of the defect counts DFI1 to DFIn of the memory array 100 is less than or equal to a critical value (for example, “500” or “1000”), the controller 200 records the defect address. For example, when the failed bit count sum of the defect counts DFI1 to DFIn of the memory array 100 is greater than the critical value, the controller 200 stops recording the defect address. The critical value may be adjusted according to actual requirements.

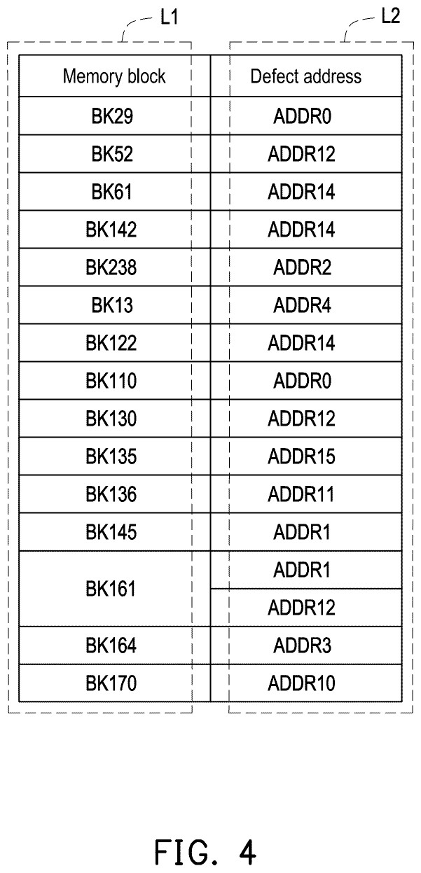

Please refer to FIG. 1, FIG. 3, and FIG. 4. FIG. 4 is a defect statistical diagram according to an embodiment of the disclosure. In the embodiment, after the defect detection method S200 ends, the controller 200 may generate the defect statistical diagram as shown in FIG. 4 according to the reference voltages VCC1 and VCC2. Column L1 of the statistical diagram records the memory blocks with the defect counts. Column L2 of the statistical diagram records the defect addresses of defects of the memory blocks.

Taking the memory block BK29 as an example, the memory block BK29 has a defect that matches the defect type to be observed at a defect address ADDR0. Taking the memory block BK161 as an example, the memory block BK161 has defects that match the defect types to be observed at defect addresses ADDR1 and ADDR12.

Taking FIG. 4 as an example, the memory array 110 has 15 memory blocks with defects that match the defect types to be observed. The memory array 110 has 16 defect addresses. In addition, the controller 200 may also display the same defect types and defect addresses of the 15 memory blocks that match the defect types to be observed using other functional test items.

Generally speaking, a conventional defect detection method for a memory array is to count defects in units of memory arrays. Once a defect quantity is greater than a critical value (for example, “500” or “1000”), the counting of the defect addresses will be invalid or incorrect. It should be noted that in the embodiment, the defects are counted in units of memory blocks. The defect quantity of each memory block is less than the total number of defects of the memory array 110. Therefore, the defect quantity may not easily exceed the critical value. In this way, the risk of invalid or incorrect counting of the defect addresses is greatly reduced.

The disclosure is not limited to the form or the content of the defect statistical diagram the embodiment.

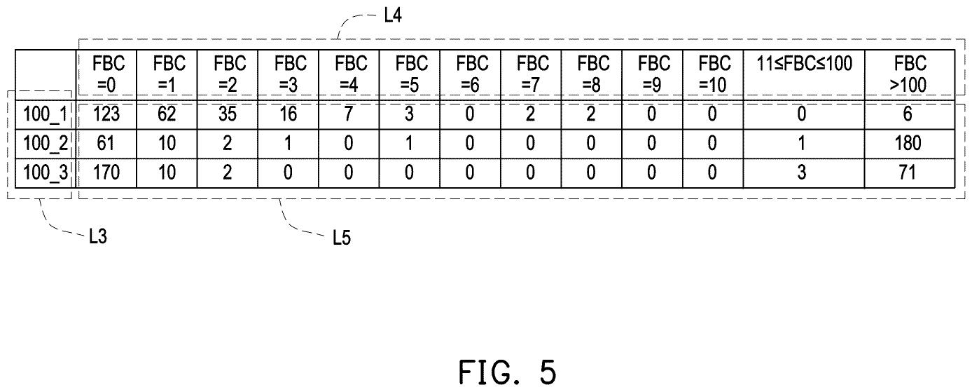

Please refer to FIG. 1 and FIG. 5. FIG. 5 is a statistical diagram of memory block quantities according to an embodiment of the disclosure. In the embodiment, the controller 200 may use multiple statistical results of defects of different defect types to generate memory block quantities corresponding to different defect types. As shown in FIG. 5, column L3 of the statistical diagram records the serial number of the memory array. Column L4 of the statistical diagram records the defect type. Column L5 of the statistical diagram records the memory block quantities corresponding to different defect types.

Taking a memory array 100_1 as an example, the memory array 100_1 has the memory block quantity of 123 for memory blocks that match the failed bit count equal to “0” (that is, FBC=0) and has the memory block quantity of 62 for memory blocks that match the failed bit count equal to “1” (that is, FBC=1), and so on.

The disclosure is not limited to the form or the content of the statistical diagram of the embodiment.

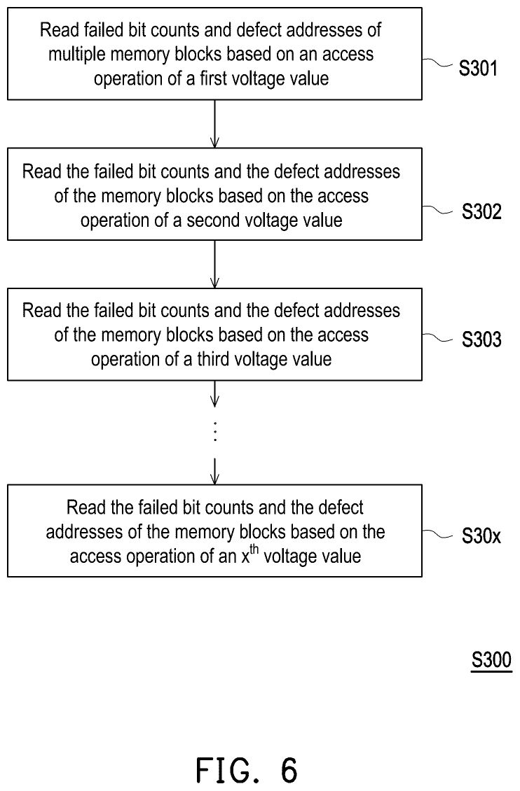

Please refer to FIG. 1 and FIG. 6. FIG. 6 is a flowchart of a defect detection method according to an embodiment of the disclosure. In the embodiment, a defect detection method S300 is used to read the failed bit counts and the defect addresses of the memory blocks BK1 to BKn corresponding to different reference voltages VCC1. The failed bit counts and the defect addresses are recorded in the defect detection method S200. The defect detection method S300 includes steps S301 to S30x. In step S301, the controller 200 sets the voltage value of the reference voltage VCC1 as a first voltage value. The controller 200 reads the failed bit counts and the defect addresses of the memory blocks BK1 to BKn based on the access operation of the first voltage value.

In step S302, the controller 200 increments the voltage value of the reference voltage VCC1 from the first voltage value to a second voltage value. The controller 200 reads the failed bit counts and the defect addresses of the memory blocks BK1 to BKn based on the access operation of the second voltage value.

In step S303, the controller 200 increments the voltage value of the reference voltage VCC1 from the second voltage value to a third voltage value. The controller 200 reads the failed bit counts and the defect addresses of the memory blocks BK1 to BKn based on the access operation of the third voltage value, and so on.

By analogy, in step S30x, the controller 200 increments the voltage value of the reference voltage VCC1 to an x^{th} voltage value. The controller 200 reads the failed bit counts and the defect addresses of the memory blocks BK1 to BKn based on the access operation of the x^{th} voltage value.

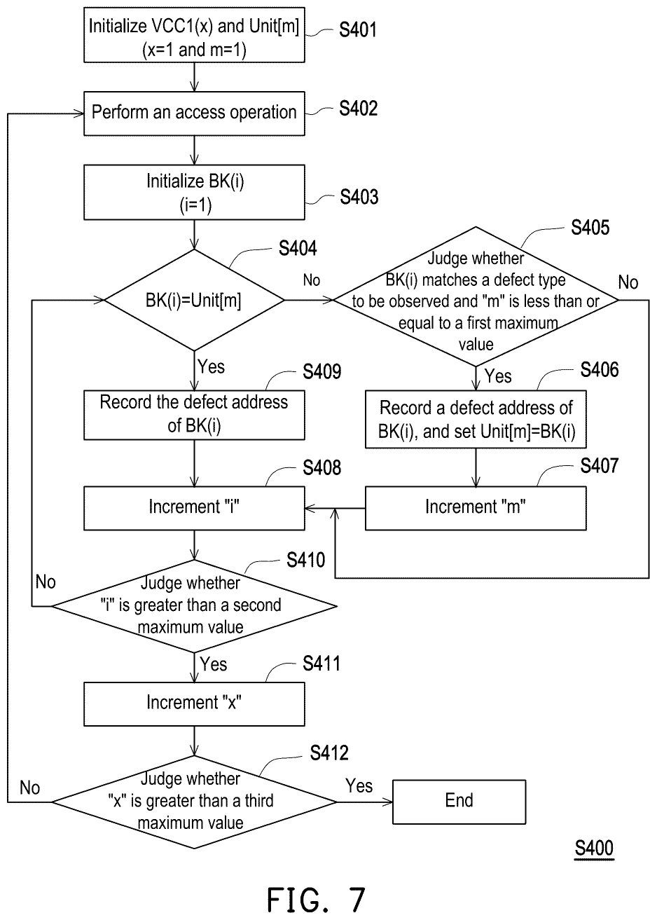

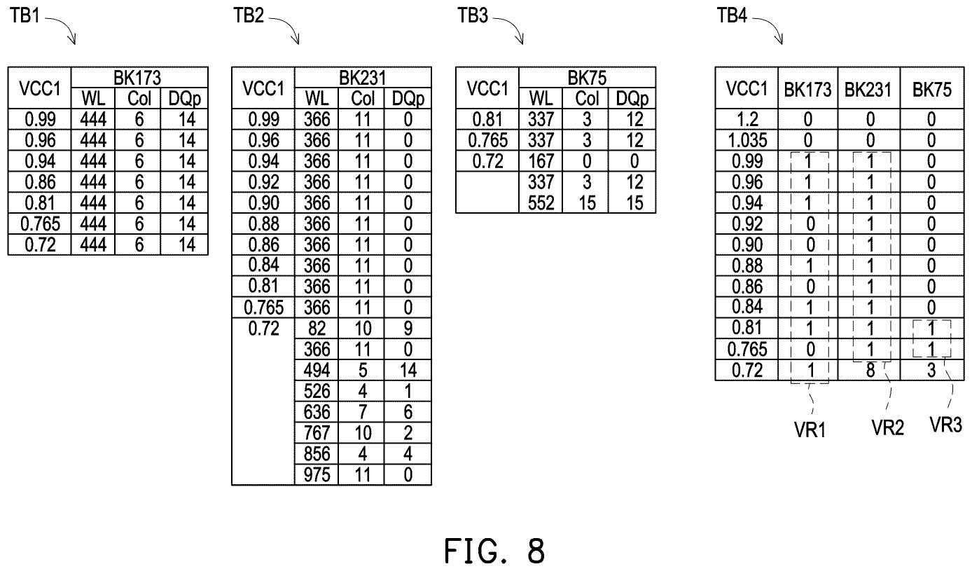

Please refer to FIG. 1, FIG. 7, and FIG. 8. FIG. 7 is a flowchart of a defect detection method according to an embodiment of the disclosure. FIG. 8 is a schematic diagram for judging a reference voltage range according to an embodiment of the disclosure. In the embodiment, the controller 200 obtains at least one of the defect counts DFI1 to DFIn corresponding to the voltage value of at least one of the reference voltages VCC1 and VCC2. The controller 200 sorts the failed bit count of at least one of the defect counts DFI1 to DFIn according to the voltage value of the at least one of the reference voltages VCC1 and VCC2.

In the embodiment, a defect detection method S400 includes steps S401 to S412. In step S401, the controller 200 initializes a voltage value of a reference voltage VCC1(x) and a target memory block Unit[m] (that is, x=1 and m=1). In the embodiment. The voltage value of the initialized reference voltage VCC1(x) is a voltage value V1 (for example, the lowest voltage value of the reference voltage VCC1).

In step S402, the access operation is performed on the memory array 110 based on the reference voltages VCC1(x) and VCC2. In the embodiment, the voltage value of the reference voltage VCC2 is fixed.

In step S403, the controller 200 initializes the selected memory block BK(i) (that is, i=1). Therefore, in step S403, the initial selected memory block BK(i) is the memory block BK1.

In step S404, the controller 200 judges whether the selected memory block BK(i) is the previously recorded target memory block Unit[m]. Initially, the target memory block Unit[m] is not set. The selected memory block BK(i) is not the previously recorded target memory block Unit[m]. Therefore, the controller 200 judges whether the selected memory block BK(i) matches the defect type to be observed and whether “m” is less than or equal to a first maximum value in step S405.

Taking the embodiment as an example, the defect type to be observed is, for example, t failed bit count equal to “1” (that is, FBC=1). The first maximum value is set to “3”. Therefore, in the embodiment, 3 memory blocks that match the defect type to be observed are observed.

In step S405, when the selected memory block BK(i) matches the defect type to be observed and “m” is less than or equal to the first maximum value, the controller 200 records the defect address of the selected memory block BK(i) in step S406, and sets the selected memory block BK(i) as the target memory block Unit[m]. Next, the controller 200 increments “m” (for example, m=m+1) in step S407, and enters step S408 to increment “i” (for example, i=i+1).

In step S405, when the selected memory block BK(i) does not match the defect type to be observed and/or “m” is greater than the first maximum value, the controller 200 does not set the target memory block Unit[m] and does not increment “m”, and enters step S408 to increment “i”.

In step S404, when the selected memory block BK(i) is the previously recorded target memory block Unit[m], it means that the target memory block Unit[m] has been set. In other words, the controller 200 may know that the selected memory block BK(i) matches the defect type to be observed and the defect address of the selected memory block BK(i). Therefore, the controller 200 records the defect address of the selected memory block BK(i) again in step S409, and enters step S408 to increment “i”.

After step S408, the controller 200 judges whether “i” is greater than a second maximum value (for example, “256”) in step S410. When “i” is less than or equal to the second maximum value, the controller 200 returns to the operation of step S404. When “i” is greater than the second maximum value, the controller 200 increments “x” (for example, x=x+1) in step S411. Therefore, the reference voltage VCC1(x) is also incremented. The controller 200 judges whether “x” is greater than a third maximum value in step S412. When “x” is less than or equal to the third maximum value, the controller 200 returns to the operation of step S402. When “x” is greater than the third maximum value, the controller 200 ends the defect detection method S400.

Based on the defect detection method S400, the controller 200 may obtain tables TB1, TB2, and TB3 as shown in FIG. 8. For example, table TB1 records a defect address of a failed bit count of a memory block BK173 (for example, a target memory block Unit[1]). The defect address includes a word line address WL, a memory column address Col, and a data (DQ) pin address DQp. When the voltage value of the reference voltage VCC1 is equal to 0.99V, 0.96V, 0.94V, 0.86V, 0.81V, 0.765V, and 0.72V, the memory block BK173 has the same defect address. For example, table TB2 records a defect address of a failed bit count of a memory block BK231 (for example, a target memory block Unit[2]). When the voltage value of the reference voltage VCC1 is equal to 0.99V to 0.765V, the memory block BK231 has the same defect address. However, when the voltage value of the reference voltage VCC1 is equal to 0.72V, the memory block BK231 has 8 defect addresses. For example, table TB3 records a defect address of a failed bit count of a memory block BK75 (for example, a target memory block Unit[3]). When the voltage value of the reference voltage VCC1 is equal to 0.81V and 0.765V, the memory block BK75 has the same defect address. However, when the voltage value of the reference voltage VCC1 is equal to 0.72V, the memory block BK75 has 3 defect addresses.

Based on the failed bit count and the voltage value of the reference voltage VCC1, table TB1, TB2, and TB3 may be organized into table TB4.

In the embodiment, the controller 200 sets a failed bit count range according to the defect type. The controller 200 obtains a voltage value range of the reference voltage corresponding to the failed bit count range.

Taking the embodiment as an example, the defect type is, for example, the failed bit count equal “1” (that is, FBC=1). Therefore, the failed bit count range may be FBC=1. In table TB4, the controller 200 may decrement the voltage value of the reference voltage VCC1 from the maximum voltage value (for example, 0.99V) of the reference voltage VCC1 to obtain the first voltage value corresponding to the failed bit count range at the beginning and the second voltage value corresponding to the failed bit count range at the end. The controller 200 subtracts the second voltage value from the first voltage value to obtain the voltage value range.

Taking the memory block BK173 as an example, the first voltage value is 0.99V. The second voltage value is 0.72V. Therefore, the controller 200 obtains a voltage value range VR1 equal to 0.27V (that is, 0.99V to 0.72V). Taking the memory block BK231 as an example, the first voltage value is 0.99V. The second voltage value is 0.765V. Therefore, the controller 200 obtains a voltage value range VR2 equal to 0.225V (that is, 0.99V to 0.765V). Taking the memory block BK75 as an example, the first voltage value is 0.81V. The second voltage value is 0.765V. Therefore, the controller 200 obtains a voltage value range VR3 equal to 0.045V (that is, 0.81V to 0.765V).

In some embodiments, the controller 200 may increment the voltage value of the reference voltage VCC1 from the minimum voltage value (for example, 0.72V) of the reference voltage VCC1 to obtain the first voltage value corresponding to the failed bit count range at the beginning and the second voltage value corresponding to the failed bit count range at the end. The controller 200 subtracts the first voltage value from the second voltage value to obtain the voltage value range.

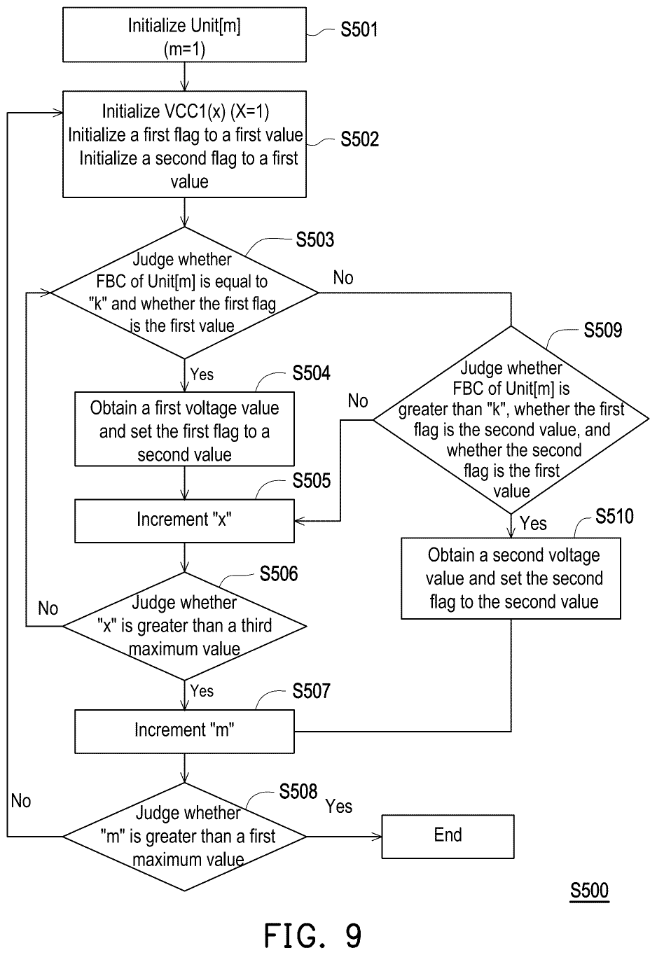

Please refer to FIG. 1, FIG. 8, and FIG. 9. FIG. 9 is a flowchart of a defect detection method according to an embodiment of the disclosure. In the embodiment, the controller 200 may use a defect detection method S500 to obtain the first voltage value and the second voltage value. The defect detection method S500 may be executed after the defect detection method S400 is completed. The defect detection method S500 includes steps S501 to S510. In step S501, the controller 200 selects the first target memory block Unit[m] (that is, m=1).

In step S502, the controller 200 initializes the voltage value, a first flag, and a second flag of the reference voltage VCC1(x). It should be noted that in the embodiment, the voltage value of the initialized reference voltage VCC1(x) is the maximum voltage value. The voltage value of the reference voltage VCC2 is fixed. In the embodiment, the first flag and the second flag are both initialized to a first value (for example, “0”).

In step S503, the controller 200 judges whether the failed bit count of the target memory block Unit[m] is equal to “k”, and judges whether the first flag is the first value. “k” may be the maximum value of the failed bit count range of the defect type. When the failed bit count of the target memory block Unit[m] is equal to “k” (that is, FBC=k) and the first flag is the first value, it means that the controller 200 finds the first voltage value corresponding to the failed bit count range at the beginning. In other words, the current voltage value of the reference voltage VCC1(x) is the first voltage value. Therefore, the controller 200 obtains the first voltage value and sets the first flag to a second value (for example, “1”) in step S504. Next, the controller 200 increments “x” (for example, x=x+1) in step S505. It should be noted that the reference voltage VCC1(x) is decremented.

In step S506, the controller 200 judges whether “x” is greater than the third maximum value. When “x” is less than or equal to the third maximum value, the controller 200 returns to the operation of step S503. When “x” is greater than the third maximum value, the controller 200 increments “m” (for example, m=m+1) in step S507. In step S508, the controller 200 judges whether “m” is greater than the first maximum value (for example, “3”). When “m” is less than or equal to the first maximum value, the controller 200 returns to the operation of step S502. Therefore, the controller 200 judges the next target memory block Unit[m]. When “m” is greater than the first maximum value, the controller 200 ends the defect detection method S500.

In step S503, when the failed bit count of the target memory block Unit[m] is not equal to “k” and/or the first flag is the second value, it means that the failed bit count of the target memory block Unit[m] corresponding to the voltage value of the reference voltage VCC1(x) does not match the defect type and/or the current voltage value of the reference voltage VCC1(x) is not the voltage value corresponding to the failed bit count range at the beginning. Therefore, the controller 200 judges whether the failed bit count of the target memory block Unit[m] is greater than “k” in step S509, whether the first flag is the second value, and whether the second flag is the first value. When the failed bit count of the target memory block Unit[m] is greater than “k”, the first flag is the second value, and the second flag is the first value, it means that after finding the first voltage value, the controller 200 obtains the second voltage value in step S510, and sets the second flag to the second value. In other words, the controller 200 uses the previous voltage value of the reference voltage VCC1(x) as the second voltage value. Next, the controller 200 enters the operation of step S507.

In step S509, in other cases, the controller 200 enters the operation of step S505. For example, when the failed bit count of the target memory block Unit[m] is less than “k”, the first flag is the first value, and/or the second flag is the second value, the controller 200 enters the operation of step S505.

The memory block BK231 (for example, the target memory block Unit[2]) is taken as a n example to illustrate steps S502 to S506, S509, and S510. The defect type is, for example, the failed bit count equal to “1” (that is, FBC=1). In step S502, the voltage value of the reference voltage VCC1(x) is equal to 1.2V. The first flag and the second flag are both initialized to the first value. In step S503, the controller 200 judges that the failed bit count of the memory block BK231 is not equal to “0”. Therefore, the controller 200 enters step S509 to judge the failed bit count of the memory block BK231, the first flag, and the second flag. The defect type is, for example, the failed bit count less than “1” and the first flag having the first value. Therefore, the controller 200 increments “x” in step S509, and enters step S503 via the judgment of step S506.

When the voltage value of the reference voltage VCC1(x) is equal to 0.99V, the controller 200 judges that the failed bit count of the memory block BK231 is equal to “1” in step S503. Therefore, the controller 200 obtains the first voltage value and sets the first flag to the second value in step S504. Next, the controller 200 increments “x” (for example, x=x+1) in step S505, and enters step S503 via the judgment of step S506.

Next, in step S503, when the failed bit count of the memory block BK231 is equal to “1”, the controller 200 loops in steps S504, S505, S506, and S503, and so on.

Next, in step S503, when the failed bit count of the memory block BK231 is equal to “0”, the controller 200 loops in steps S509, S505, S506, and S503, and so on.

When the voltage value of the reference voltage VCC1(x) is 0.72V, the failed bit count of the memory block BK231 is equal to “8”, and the controller 200 enters step S509 to judge that the failed bit count of the memory block BK231 is greater than “1”, the first flag is the second value, and the second flag is the first value. Therefore, the controller 200 uses the previous voltage value (that is, 0.765V) of the reference voltage VCC1(x) as the second voltage value in step S510, and sets the second flag to the second value. Therefore, the controller 200 obtains the voltage value range VR2 equal to 0.225V.

For the memory block BK173, in step S510, the controller 200 uses the current voltage value (that is, 0.72V) of the reference voltage VCC1(x) as the second voltage value.

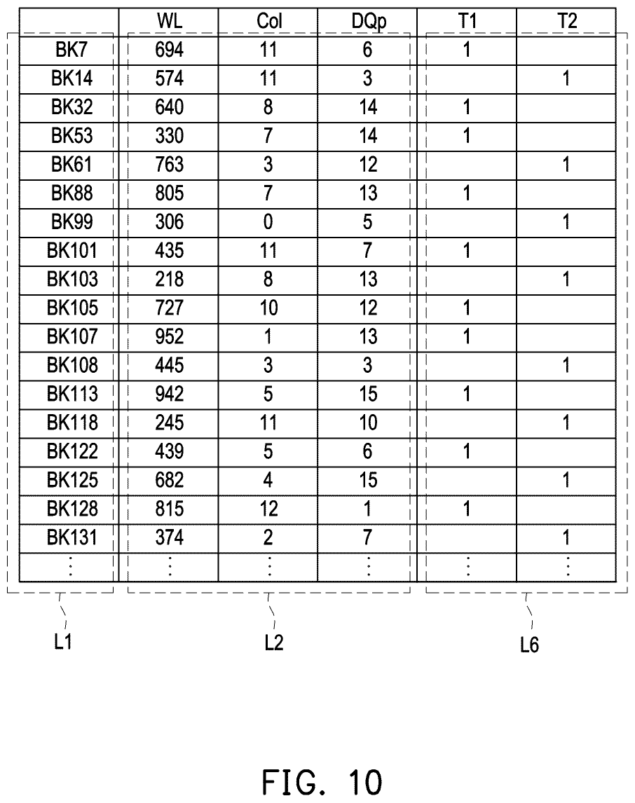

Please refer to FIG. 1 and FIG. 10. FIG. 10 is a defect statistical diagram according to an embodiment of the disclosure. In the embodiment, the controller 200 may use memory test items T1 and T2 to execute the defect detection method S100, thereby obtaining the defect counts DFI1 to DFIn corresponding to different memory test items. Column L1 of the statistical diagram records the memory blocks with defects. Column L2 of the statistical diagram records the defect addresses of the defects of the memory blocks. Column L6 of the statistical diagram records the defect counts of the defects of the memory blocks in the test items T1 and T2.

For example, the test item T1 is different from the test item T2. Therefore, the defect count of the defects in the test item T1 may be different from the defect count of the defects in the test item T2. Testers or developers may analyze the defects based on FIG. 10.

In summary, the defect detection method of the disclosure divides the memory array into the memory blocks to obtain the defect counts of the memory blocks after the access operation. The defect types of the memory blocks may be judged according to the defect counts. The defect count of a single memory block is lower than the defect count of the memory array. In this way, the defect type of the memory block may be easily judged.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A defect detection method for a memory device, wherein the memory device comprises a memory array, wherein the memory array performs an access operation according to a reference voltage, the defect detection method comprising:
dividing the memory array into a plurality of memory blocks;
adjusting a voltage value of the reference voltage to sequentially perform the access operation on the memory blocks, and receiving a plurality of defect counts of the memory blocks after the access operation; and
judging a defect type of the memory blocks according to the defect counts.

2. The defect detection method according to claim 1, wherein the defect counts comprise a failed bit count and a failed bit line count, the defect detection method comprising:
defining the defect type of the memory blocks according to the failed bit count and the failed bit line count.

3. The defect detection method according to claim 2, wherein the step of defining the defect type of the memory blocks according to the failed bit count and the failed bit line count comprises:
when the failed bit count corresponding to a first memory block among the memory blocks is equal to 0 and the failed bit line count corresponding to the first memory block is equal to 0, judging the first memory block to be a pass memory block.

4. The defect detection method according to claim 3, wherein the step of defining the defect type of the memory blocks according to the failed bit count and the failed bit line count further comprises:
when the failed bit count corresponding to the first memory block is greater than 0 and the failed bit line count corresponding to the first memory block is equal to 1, judging that the first memory block has a bit line failure.

5. The defect detection method according to claim 3, wherein the step of defining the defect type of the memory blocks according to the failed bit count and the failed bit line count further comprises:
when the failed bit count corresponding to the first memory block is equal to a and the failed bit line count corresponding to the first memory block is greater than 1, judging that the first memory block has a bit defects,
where a is a positive integer.

6. The defect detection method according to claim 3, wherein the step of defining the defect type of the memory blocks according to the failed bit count and the failed bit line count further comprises:
when the failed bit line count corresponding to the first memory block is greater than a preset value, judging that the first memory block has a data failure.

7. The defect detection method according to claim 1, further comprising:
sorting a failed bit count of at least one of the defect counts according to the voltage value of the reference voltage.

8. The defect detection method according to claim 7, further comprising:
setting a failed bit count range according to the defect type; and
obtaining a voltage value range of the reference voltage corresponding to the failed bit count range.

9. The defect detection method according to claim 8, wherein the step of obtaining the voltage value range of the reference voltage corresponding to the failed bit count range comprises:
decrementing the voltage value of the reference voltage from a maximum voltage value of the reference voltage to obtain a first voltage value corresponding to the failed bit count range at a beginning and a second voltage value corresponding to the failed bit count range at an end; and
subtracting the second voltage value from the first voltage value to obtain the voltage value range.

10. The defect detection method according to claim 8, wherein the step of obtaining the voltage value range of the reference voltage corresponding to the failed bit count range comprises:
incrementing the voltage value of the reference voltage from a minimum voltage value of the reference voltage to obtain a first voltage value corresponding to the failed bit count range at a beginning and a second voltage value corresponding to the failed bit count range at an end; and
subtracting the first voltage value from the second voltage value to obtain the voltage value range.

11. The defect detection method according to claim 1, further comprising:
when a failed bit count sum of the defect counts of the memory array is less than or equal to a critical value, recording a plurality of defect addresses of the memory array; and
when the failed bit count sum of the defect counts of the memory array is greater than the critical value, stopping recording the defect addresses.

12. The defect detection method according to claim 11, wherein each of the defect addresses comprises a word line address, a memory column address, and a data pin address.

13. The defect detection method according to claim 12, wherein each of the defect addresses further comprises a memory array address and a memory block address.

14. The defect detection method according to claim 1, wherein the defect detection method is executed based on a plurality of different memory test items, thereby obtaining the defect counts corresponding to the different memory test items.

15. The defect detection method according to claim 1, further comprising:
generating a status flag according to the defect type; and
deciding whether to display a defect address corresponding to the defect type according to the status flag.

16. The defect detection method according to claim 15, wherein a plurality of failed bit counts of the memory blocks and a sequence of the memory blocks are used to decide whether to display the defect address corresponding to the defect type and display an address sequence.

17. The defect detection method according to claim 16, further comprising:
when a failed bit count corresponding to a first memory block among the memory blocks is equal to 0, judging the first memory block to be a pass memory block, and generating a flag that the first memory block is in a pass memory block status and recording a pass address.

18. The defect detection method according to claim 16, further comprising:
when a sum of the failed bit counts of the memory array is greater than a critical value, stopping recording the defect address.

19. The defect detection method according to claim 1, further comprising:
selecting a first functional test item to test the memory blocks to record failed bit counts and failed bit line counts of the memory blocks; and
displaying the failed bit counts and the failed bit line counts of the memory blocks using a second functional test item.
